(19) United States
(12) Patent Application Publication
(10) Pub. No.: US 2025/0351427 A1
(43) Pub. Date: Nov. 13, 2025

(54) SEMICONDUCTOR STRUCTURE

(71) Applicant: United Microelectronics Corp., Hsinchu (TW)

(72) Inventors: Te-Chi YEN, Tainan City (TW); Ling-Chun CHOU, Tainan City (TW); Yu-Hung CHANG, Tainan City (TW); Pin-Tseng CHEN, Kaohsiung City (TW); Kun-Hsien LEE, Tainan City (TW)

(21) Appl. No.: 18/739,367

(22) Filed: Jun. 11, 2024

(30) Foreign Application Priority Data
May 13, 2024 (TW) 113117627

(51) Int. Cl. H01L 29/78; H01L 29/06

(52) U.S. Cl. CPC H10D 30/65; H10D 62/116

(57) ABSTRACT

A semiconductor structure is provided. The semiconductor structure includes a substrate, a first well in the substrate and having a first side surface, a second well in the substrate and having a second side surface, a third well in the substrate, an isolation structure in the substrate and between the first well and the second well, a drain region in the first well, a source region in the third well, and a gate structure on the substrate. The second well is between the first well and the third well. The first side surface of the first well faces the second side surface of the second well. The first side surface of the first well is apart from the second side surface of the second well.

This application claims the benefit of Taiwan application Serial No. 113117627, filed May 13, 2024, the subject matter of which is incorporated herein by reference.

### BACKGROUND

### Technical Field

The disclosure relates to a semiconductor structure, and more particularly relates to a metal oxide semiconductor structure.

### Description of the Related Art

Metal-Oxide-Semiconductor Field-Effect Transistor (MOSFET) is one of the transistors widely used in today's integrated circuits. MOSFETs may include three categories, planar MOSFETs, lateral diffused MOSFETs (LDMOS) and vertical diffused MOSFETs according to the structure difference. In comparison with other MOSFETs, the LDMOS is capable of delivering more current per unit area because its asymmetric structure provides a short channel between the drain and the source of the LDMOS. In existing LDMOS designs, high breakdown voltage is usually achieved by reducing the doping concentration of the N-type well and/or P-type well of LDMOS below the isolation structure. However, reducing the doping concentration of the N-type well and/or P-type well requires more masks and more process steps, which results in high manufacturing costs and is difficult to be compatible with other manufacturing processes. In addition, the breakdown voltage of existing LDMOS is still insufficient to meet demand.

### SUMMARY

According to some embodiments of the present disclosure, a semiconductor structure is provided. The semiconductor structure includes a substrate, a first well in the substrate and having a first side surface, a second well in the substrate and having a second side surface, a third well in the substrate, an isolation structure in the substrate and between the first well and the second well, a drain region in the first well, a source region in the third well, and a gate structure on the substrate. The second well is between the first well and the third well. The first side surface of the first well faces the second side surface of the second well. The first side surface of the first well is apart from the second side surface of the second well.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIG. 1 illustrates a schematic view of a semiconductor structure according to some embodiments of the present disclosure.

FIG. 2 illustrates a schematic view of a semiconductor structure according to some embodiments of the present disclosure.

FIG. 3 illustrates a schematic view of a semiconductor structure according to some embodiments of the present disclosure.

FIG. 4 illustrates a schematic view of a semiconductor structure according to some embodiments of the present disclosure.

FIG. 5 illustrates a schematic view of a semiconductor structure according to some embodiments of the present disclosure.

FIGS. 6A and 6B shows testing results of semiconductor structures according to some embodiments of the present disclosure.

### DETAILED DESCRIPTION

Various embodiments will be described more fully hereinafter with reference to accompanying drawings, which are provided for illustrative and explaining purposes rather than a limiting purpose. For clarity, the components may not be drawn to scale. In addition, some components and/or reference numerals may be omitted from some drawings. It is contemplated that the elements and features of one embodiment can be beneficially incorporated in another embodiment without further recitation. In the following methods for manufacturing semiconductor devices, there may be one or more additional operations between the operations described, and the order of the operations may vary. The illustration uses the same/similar reference numerals to indicate the same/similar elements.

As used in the specification and the appended claims, the ordinals such as “first”, “second” and the like to describe elements do not imply or represent a specific position in the structure, or the order of arrangement, or the order of manufacturing. The ordinals are only used to clearly distinguish multiple elements with the same name. As used in the specification and the appended claims, spatial relation terms such as “on”, “above”, “over”, “upper,” “top”, “below”, “beneath”, “under”, “lower”, “bottom” and the like may be used to describe the relative spatial relations or positional relations between one element(s) and another element(s) as illustrated in the drawings, and these spatial relations or positional relations, unless specified otherwise, can be direct or indirect. The spatial relation terms are intended to encompass different orientations of structures in addition to the orientation depicted in the drawings. The structure can be inverted or rotated by various angles, and the spatial relation descriptions used herein can be interpreted accordingly. As used in the specification and the appended claims, the singular forms “a,” “an,” and “the” are intended to include the plural forms as well, unless the context clearly indicates otherwise. As used in the specification and the appended claims, term “adjoin” refers to “be adjacent to and contact”.

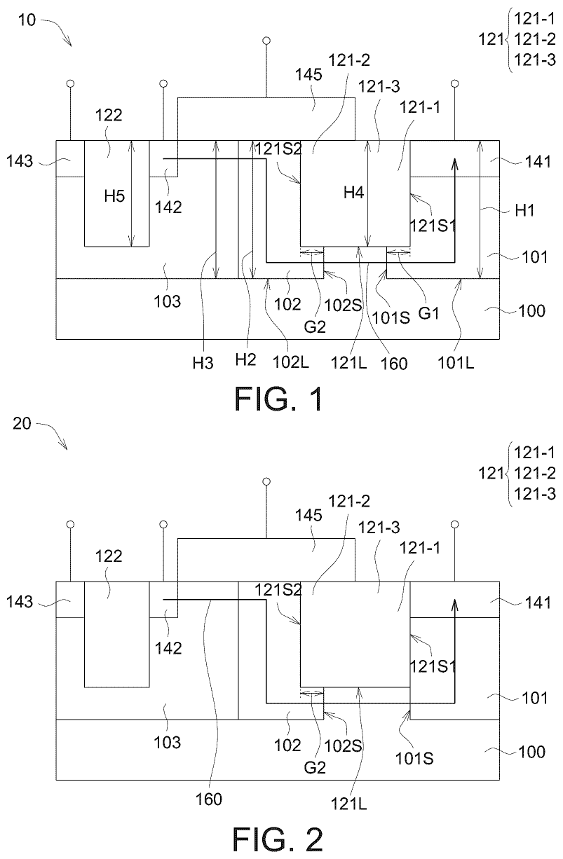

Referring to FIG. 1, FIG. 1 illustrates a schematic view of a semiconductor structure according to some embodiments of the present disclosure. The semiconductor structure includes a transistor structure 10. The transistor structure 10 can be a lateral diffused MOSFET. The transistor structure 10 includes a substrate 100, a first well 101, a second well 102, a third well 103, an isolation structure 121, a drain region 141, a source region 142 and a gate structure 145. The substrate 100 can be formed by a semiconductor material such as monocrystalline silicon, polycrystalline silicon, germanium, diamond, gallium arsenide, silicon carbide, indium arsenide, indium phosphide, silicon germanium carbide, gallium arsenide phosphide, gallium indium phosphide, and any combination thereof. The substrate 100 includes dopant. For example, the dopant can be an electron donor or electron acceptor. The substrate 100 may have a first conductivity type or a second conductivity type different from the first conductivity type depending on the type of the dopant. For example, the first conductivity type is N-type, and the second conductivity type is P-type. The substrate 100 having the first conductivity type can be used for P-type lateral diffused MOSFET. The substrate 100 having the second conductivity type can be used for N-type lateral diffused MOSFET. The following description uses the substrate 100 having the second conductivity type (P-type) and a N-type lateral diffused MOSFET as embodiments to illustrate the present disclosure, but the present disclosure can also be applied to a P-type lateral diffused MOSFET.

The first well 101 is in the substrate 100. The first well 101 can be formed by introducing dopants into the substrate 100. The first well 101 has the first conductivity type. The second well 102 is in the substrate 100. The second well 102 can be formed by introducing dopants into the substrate 100. The second well 102 has the first conductivity type. The third well 103 in the substrate 100. The third well 103 can be formed by introducing dopants into the substrate 100. The third well 103 has the second conductivity type. The second well 102 is between the first well 101 and the third well 103. The second well 102 adjoins the third well 103. A P-N junction is formed at the contact interface between the second well 102 and the third well 103 since the conductivity type of the second well 102 is different from the conductivity type of the third well 103. A P-N junction is formed at the contact interface between the first well 101 and the substrate 100 since the conductivity type of the first well 101 is different from the conductivity type of the substrate 100. A P-N junction is formed at the contact interface between the second well 102 and the substrate 100 since the conductivity type of the second well 102 is different from the conductivity type of the substrate 100. The isolation structure 121 is in the substrate 100 and between the first well 101 and the second well 102. The first well 101 and the second well 102 are separated by the isolation structure 121. For example, the isolation structure 121 is a shallow trench isolation structure (STI). A portion of the first well 101 extends below the isolation structure 121. A portion of the second well 102 extends below the isolation structure 121.

The drain region 141 is in the first well 101. The drain region 141 can be formed by introducing dopants into the first well 101. The drain region 141 has the first conductivity type. The doping concentration of the drain region 141 can be higher than the doping concentration of the first well 101 and the doping concentration of the second well 102. The source region 142 in the third well 103. The source region 142 can be formed by introducing dopants into the third well 103. The source region 142 has the first conductivity type. The doping concentration of the source region 142 can be higher than the doping concentration of the first well 101 and the doping concentration of the second well 102. The gate structure 145 is on the substrate 100 and between the drain region 141 and the source region 142. The gate structure 145 may include a gate dielectric film and a gate electrode film on the gate dielectric film. The gate electrode film may have a single-layer or multi-layer structure. The gate structure 145 may partially overlap the third well 103 and the isolation structure 121 in a longitudinal direction. The gate structure 145 may overlap or partially overlap the second well 102 in the longitudinal direction. In some embodiments, the gate structure 145 is closer to the source region 142 than to the drain region 141.

The transistor structure 10 may further include a doping region 143 and an isolation structure 122 in the third well 103. The isolation structure 122 is between the doping region 143 and the source region 142. The doping region 143 and the source region 142 are separated by the isolation structure 122. The doping region 143 can be formed by introducing dopants into the third well 103. The doping region 143 has the second conductivity type. The doping concentration of the doping region 143 can be higher than the doping concentration of the third well 103. The third well 103 may cover a lower surface of the isolation structure 122. The doping region 143 may be a body region of the lateral diffused MOSFET. For example, the isolation structure 122 is a shallow trench isolation structure.

A depth H1 of the first well 101 in the longitudinal direction is greater than a depth H4 of the isolation structure 121 in the longitudinal direction. A depth H2 of the second well 102 in the longitudinal direction is greater than the depth H4 of the isolation structure 121 in the longitudinal direction. A lower surface 121L of the isolation structure 121 is higher than a lower surface 101L of the first well 101 and a lower surface 102L of the second well 102. A depth H3 of the third well 103 in the longitudinal direction is greater than a depth H5 of the isolation structure 122 in the longitudinal direction. The depth H1 of the first well 101 in the longitudinal direction, the depth H2 of the second well 102 in the longitudinal direction and the depth H3 of the third well 103 in the longitudinal direction may be the same as or different from each other. The depth H4 of the isolation structure 121 in the longitudinal direction and the depth H5 of the isolation structure 122 in the longitudinal direction may be the same as or different from each other. At least a portion of the lower surface 121L of the isolation structure 121 is not covered by the first well 101 and the second well 102 and can directly contact the substrate 100. In the embodiment shown in FIG. 1, a portion of the lower surface 121L of the isolation structure 121 is covered by the first well 101, another portion of the lower surface 121L of the isolation structure 121 is covered by the second well 102, and yet another portion (or the other portion) of the lower surface 121L of the isolation structure 121 is not covered by the first well 101 and the second well 102.

The isolation structure 121 may partially overlap the first well 101 in a longitudinal direction. The isolation structure 121 may partially overlap the second well 102 in a longitudinal direction. The isolation structure 121 includes a first portion 121-1, a second portion 121-2 and a third portion 121-3 between the first portion 121-1 and the second portion 121-2. The first portion 121-1 overlaps the first well 101 in the longitudinal direction and directly contacts the first well 101 and the drain region 141. The second portion 121-2 overlaps the second well 102 in the longitudinal direction and directly contacts the second well 102. The third portion 121-3 does not overlap the first well 101 and the second well 102 in the longitudinal direction. The third portion 121-3 may directly contact the substrate 100.

The first well 101 has a side surface 101S. The side surface 101S may be below the isolation structure 121. The second well 102 has a side surface 102S. The side surface 102S may be below the isolation structure 121. The side surface 101S of the first well 101 faces the side surface 102S of the second well 102. The side surface 101S of the first well 101 is apart from the side surface 102S of the second well 102. The substrate 100 may directly contact or cover the side surface 101S of the first well 101 and the side surface 102S of the second well 102.

The isolation structure 121 has a sidewall 121S1 and a sidewall 121S2 opposite to the sidewall 121S1. The sidewall 121S1 of the isolation structure 121 is covered by the first well 101. The sidewall 121S2 of the isolation structure 121 is covered by the second well 102. A distance G1 between the sidewall 121S1 of the isolation structure 121 and the side surface 101S of the first well 101 is greater than zero. A distance G2 between the sidewall 121S2 of the isolation structure 121 and the side surface 102S of the second well 102 is greater than zero. The distances G1 and G2 are along the lateral direction. The lateral direction is perpendicular to the longitudinal direction. The distance G1 may be equal to the distance G2 or may not be equal to the distance G2.

When the transistor structure 10 is in an “on” state, current flows from the source region 142 to the drain region 141 through the third well 103, the second well 102, the substrate 100 and the first well 101, the current path can be represented as the current path 160 shown in FIG. 1. In some embodiments, when the transistor structure 10 is in an “on” state, current flows from the source region 142 to the drain region 141 through the third well 103, the P-N junction between the third well 103 and the second well 102, the second well 102, the P-N junction between the second well 102 and the substrate 100 (e.g. the side surface 102S), the substrate 100, the P-N junction between the substrate 100 and the first well 101 (e.g. the side surface 101S) and the first well 101.

Referring to FIG. 2, FIG. 2 illustrates a schematic view of a semiconductor structure according to some embodiments of the present disclosure. The semiconductor structure includes a transistor structure 20. The transistor structure 20 can be a lateral diffused MOSFET. The difference between the transistor structure 20 and the transistor structure 10 shown in FIG. 1 is that, the lower surface 121L of the isolation structure 121 of the transistor structure 20 is not coved by the first well 101, and the isolation structure 121 does not overlap the first well 101 in the longitudinal direction. In the present embodiment, a portion of the lower surface 121L of the isolation structure 121 is covered by the second well 102, and another portion of the lower surface 121L of the isolation structure 121 is not covered by the first well 101 and the second well 102 and directly contact the substrate 100. The first portion 121-1 of the isolation structure 121 does not overlap the first well 101 in the longitudinal direction and the first portion 121-1 of the isolation structure 121 directly contacts the substrate 100. The second portion 121-2 of the isolation structure 121 overlaps the second well 102 in the longitudinal direction and directly contacts the second well 102. The third portion 121-3 of the isolation structure 121 does not overlap the first well 101 and the second well 102 in the longitudinal direction. The third portion 121-3 may directly contact the substrate 100.

A distance in the lateral direction between the sidewall 121S1 of the isolation structure 121 and the side surface 101S of the first well 101 is equal to zero. The side surface 101S of the first well 101 is aligned with the sidewall 121S1 of the isolation structure 121 in the longitudinal direction. A distance G2 between the sidewall 121S2 of the isolation structure 121 and the side surface 102S of the second well 102 is greater than zero.

When the transistor structure 20 is in an “on” state, current flows from the source region 142 to the drain region 141 through the third well 103, the second well 102, the substrate 100 and the first well 101, the current path can be represented as the current path 160 shown in FIG. 2. In some embodiments, when the transistor structure 20 is in an “on” state, current flows from the source region 142 to the drain region 141 through the third well 103, the P-N junction between the third well 103 and the second well 102, the second well 102, the P-N junction between the second well 102 and the substrate 100 (e.g. the side surface 102S), the substrate 100, the P-N junction between the substrate 100 and the first well 101 (e.g. the side surface 101S) and the first well 101.

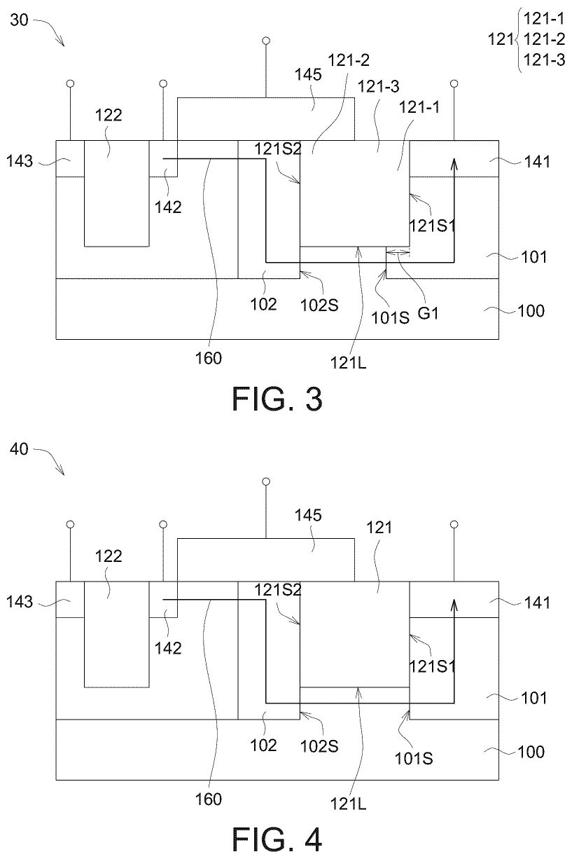

Referring to FIG. 3, FIG. 3 illustrates a schematic view of a semiconductor structure according to some embodiments of the present disclosure. The semiconductor structure includes a transistor structure 30. The transistor structure 30 can be a lateral diffused MOSFET. The difference between the transistor structure 30 and the transistor structure 10 shown in FIG. 1 is that, the lower surface 121L of the isolation structure 121 of the transistor structure 30 is not coved by the second well 102, and the isolation structure 121 does not overlap the second well 102 in the longitudinal direction. In the present embodiment, a portion of the lower surface 121L of the isolation structure 121 is covered by the first well 101, and another portion of the lower surface 121L of the isolation structure 121 is not covered by the first well 101 and the second well 102 and directly contact the substrate 100. The first portion 121-1 of the isolation structure 121 overlaps the first well 101 in the longitudinal direction and directly contacts the first well 101 . . . . The second portion 121-2 of the isolation structure 121 does not overlap the second well 102 in the longitudinal direction and the second portion 121-2 of the isolation structure 121 directly contacts the substrate 100. The third portion 121-3 of the isolation structure 121 does not overlap the first well 101 and the second well 102 in the longitudinal direction. The third portion 121-3 may directly contact the substrate 100.

A distance G1 between the sidewall 121S1 of the isolation structure 121 and the side surface 101S of the first well 101 is greater than zero. A distance in the lateral direction between the sidewall 121S2 of the isolation structure 121 and the side surface 102S of the second well 102 is equal to zero. The side surface 102S of the second well 102 is aligned with the sidewall 121S2 of the isolation structure 121 in the longitudinal direction.

When the transistor structure 30 is in an “on” state, current flows from the source region 142 to the drain region 141 through the third well 103, the second well 102, the substrate 100 and the first well 101, the current path can be represented as the current path 160 shown in FIG. 3. In some embodiments, when the transistor structure 30 is in an “on” state, current flows from the source region 142 to the drain region 141 through the third well 103, the P-N junction between the third well 103 and the second well 102, the second well 102, the P-N junction between the second well 102 and the substrate 100 (e.g. the side surface 102S), the substrate 100, the P-N junction between the substrate 100 and the first well 101 (e.g. the side surface 101S) and the first well 101.

Referring to FIG. 4, FIG. 4 illustrates a schematic view of a semiconductor structure according to some embodiments of the present disclosure. The semiconductor structure includes a transistor structure 40. The transistor structure 40 can be a lateral diffused MOSFET. The difference between the transistor structure 40 and the transistor structure 10 shown in FIG. 1 is that, the lower surface 121L of the isolation structure 121 of the transistor structure 40 is not coved by the first well 101 and the second well 102, and the isolation structure 121 does not overlap the first well 101 and the second well 102 in the longitudinal direction. In the present embodiment, the lower surface 121L of the isolation structure 121 is completely not covered by the first well 101 and the second well 102, and the lower surface 121L of the isolation structure 121 directly contacts the substrate 100.

A distance in the lateral direction between the sidewall 121S1 of the isolation structure 121 and the side surface 101S of the first well 101 is equal to zero. The side surface 101S of the first well 101 is aligned with the sidewall 121S1 of the isolation structure 121 in the longitudinal direction. A distance in the lateral direction between the sidewall 121S2 of the isolation structure 121 and the side surface 102S of the second well 102 is equal to zero. The side surface 102S of the second well 102 is aligned with the sidewall 121S2 of the isolation structure 121 in the longitudinal direction.

When the transistor structure 40 is in an “on” state, current flows from the source region 142 to the drain region 141 through the third well 103, the second well 102, the substrate 100 and the first well 101, the current path can be represented as the current path 160 shown in FIG. 4. In some embodiments, when the transistor structure 40 is in an “on” state, current flows from the source region 142 to the drain region 141 through the third well 103, the P-N junction between the third well 103 and the second well 102, the second well 102, the P-N junction between the second well 102 and the substrate 100 (e.g. the side surface 102S), the substrate 100, the P-N junction between the substrate 100 and the first well 101 (e.g. the side surface 101S) and the first well 101.

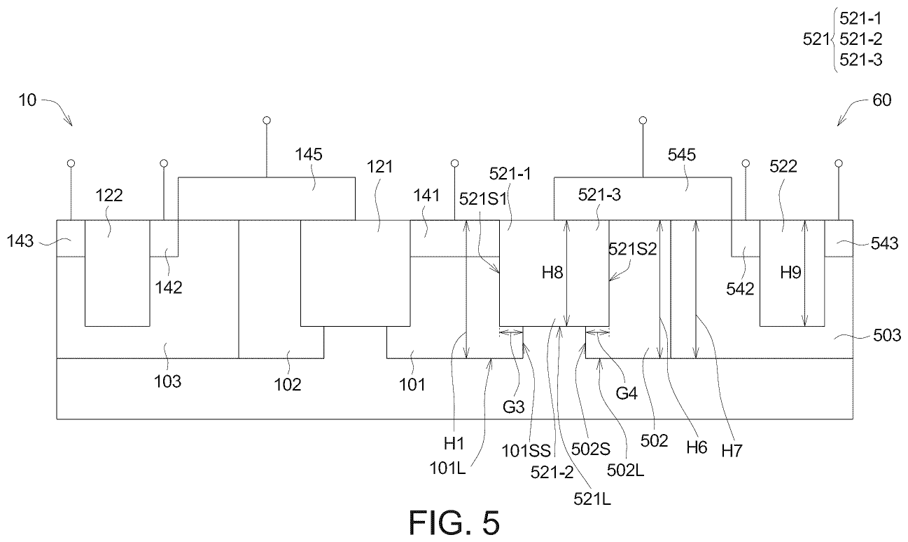

Referring to FIG. 5, FIG. 5 illustrates a schematic view of a semiconductor structure according to some embodiments of the present disclosure. The semiconductor structure includes a transistor structure 10 and a transistor structure 60. The transistor structure 60 is adjacent to the transistor structure 10. The transistor structure 60 includes a substrate 100, a first well 101, a second well 502, a third well 503, an isolation structure 521, a drain region 141, a source region 542, a gate structure 545, a doping region 543 and an isolation structure 522. The transistor structure 60 and the transistor structure 10 may share the first well 101, the drain region 141 and the substrate 100. The second well 502 and the third well 503 are in the substrate 100. The second well 502 adjoins the third well 503. The second well 502 is between the first well 101 and the third well 503. The second well 502 can be formed by introducing dopants into the substrate 100. The second well 502 has the first conductivity type. The third well 503 can be formed by introducing dopants into the substrate 100. The third well 503 has the second conductivity type. A P-N junction is formed at the contact interface between the second well 502 and the third well 503 since the conductivity type of the second well 502 is different from the conductivity type of the third well 503. A P-N junction is formed at the contact interface between the second well 502 and the substrate 100 since the conductivity type of the second well 502 is different from the conductivity type of the substrate 100. The isolation structure 521 is in the substrate 100 and between the first well 101 and the second well 502. The first well 101 and the second well 502 are separated by the isolation structure 521. For example, the isolation structures 521 and 522 are shallow trench isolation structures.

The drain region 141 has the first conductivity type. The doping concentration of the drain region 141 can be higher than the doping concentration of the first well 101 and the doping concentration of the second well 502. The source region 542 in the third well 503. The source region 542 can be formed by introducing dopants into the third well 503. The source region 542 has the first conductivity type. The doping concentration of the source region 542 can be higher than the doping concentration of the first well 101 and the doping concentration of the second well 502. The gate structure 545 is on the substrate 100 and between the drain region 141 and the source region 542. The gate structure 545 may include a gate dielectric film and a gate electrode film on the gate dielectric film. The gate electrode film may have a single-layer or multi-layer structure. The gate structure 545 may partially overlap the third well 503 and the isolation structure 521 in the longitudinal direction. The gate structure 545 may overlap or partially overlap the second well 502 in the longitudinal direction. In some embodiments, the gate structure 545 is closer to the source region 542 than to the drain region 141. The isolation structure 522 is between the doping region 543 and the source region 542. The doping region 543 and the source region 542 are separated by the isolation structure 522. The doping region 543 can be formed by introducing dopants into the third well 503. The doping region 543 has the second conductivity type. The doping concentration of the doping region 543 can be higher than the doping concentration of the third well 503. The third well 503 may cover a lower surface of the isolation structure 522. The doping region 543 may be a body region of the lateral diffused MOSFET.

The depth H1 of the first well 101 in the longitudinal direction is greater than a depth H8 of the isolation structure 521 in the longitudinal direction. A depth H6 of the second well 502 in the longitudinal direction is greater than the depth H8 of the isolation structure 521 in the longitudinal direction. A lower surface 521L of the isolation structure 521 is higher than the lower surface 101L of the first well 101 and a lower surface 502L of the second well 502. A depth H7 of the third well 503 in the longitudinal direction is greater than a depth H9 of the isolation structure 522 in the longitudinal direction. The depth H1 of the first well 101 in the longitudinal direction, the depth H6 of the second well 502 in the longitudinal direction and the depth H7 of the third well 503 in the longitudinal direction may be the same as or different from each other. The depth H8 of the isolation structure 521 in the longitudinal direction and the depth H9 of the isolation structure 522 in the longitudinal direction may be the same as or different from each other.

At least a portion of the lower surface 521L of the isolation structure 521 is not covered by the first well 101 and the second well 502. In the present embodiment, a portion of the lower surface 521L of the isolation structure 521 is covered by the first well 101, another portion of the lower surface 521L of the isolation structure 521 is covered by the second well 502, and yet another portion of the lower surface 521L of the isolation structure 521 can directly contact the substrate 100. The isolation structure 521 includes a first portion 521-1, a second portion 521-2 and a third portion 521-3 between the first portion 521-1 and the second portion 521-2. The first portion 521-1 overlaps the first well 101 in the longitudinal direction and directly contacts the first well 101 and the drain region 141. The second portion 121-2 overlaps the second well 502 in the longitudinal direction and directly contacts the second well 502. The third portion 521-3 does not overlap the first well 101 and the second well 102 in the longitudinal direction. The third portion 521-3 may directly contact the substrate 100.

The first well 101 has a side surface 101SS. The side surface 101SS may be below the isolation structure 521. The second well 502 has a side surface 502S. The side surface 502S may be below the isolation structure 521. The side surface 101SS of the first well 101 faces the side surface 502S of the second well 502. The side surface 101SS of the first well 101 is apart from the side surface 502S of the second well 502. The substrate 100 may directly contact or cover the side surface 101SS of the first well 101 and the side surface 502S of the second well 502.

The isolation structure 521 has a sidewall 521S1 and a sidewall 521S2 opposite to the sidewall 521S1. The sidewall 521S1 is covered by the first well 101. The sidewall 521S2 is covered by the second well 502. A distance G3 between the sidewall 521S1 of the isolation structure 521 and the side surface 101SS of the first well 101 is greater than zero. A distance G4 between the sidewall 521S2 of the isolation structure 521 and the side surface 502S of the second well 502 is greater than zero. The distances G3 and G4 are along the lateral direction. The distance G3 may be equal to the distance G4 or may not be equal to the distance G4. When the transistor structure 60 is in an “on” state, the current path of the transistor structure 60 can be similar to the current path of the transistor structure 10.

In FIG. 5, the relative positional relationship between the isolation structure 521, the first well 101 and the second well 502 in the transistor structure 60, and the manner in which the lower surface 521L of the isolation structure 521 is covered by the first well 101 and the second well 502 are similar to that of the transistor structure 10, but the present disclosure is not limited thereto. The relative positional relationship between the isolation structure 521, the first well 101 and the second well 502 in the transistor structure 60, and the manner in which the lower surface 521L of the isolation structure 521 is covered by the first well 101 and the second well 502 may be similar to that of transistor structure 20 or 30 or 40. In addition, the transistor structure 10 of the semiconductor structure shown in FIG. 5 can be replaced by the transistor structure 20 or 30 or 40.

According to the above embodiments, the transistor structure of the semiconductor structure of the present disclosure includes a first well, a second well and an isolation structure between the first well and the second well, the side surface of the first well is apart from the side surface of the second well which faces the side surface of the first well. That is, at least a portion of the lower surface of the isolation structure is not covered by the well (including the first well and the second well).

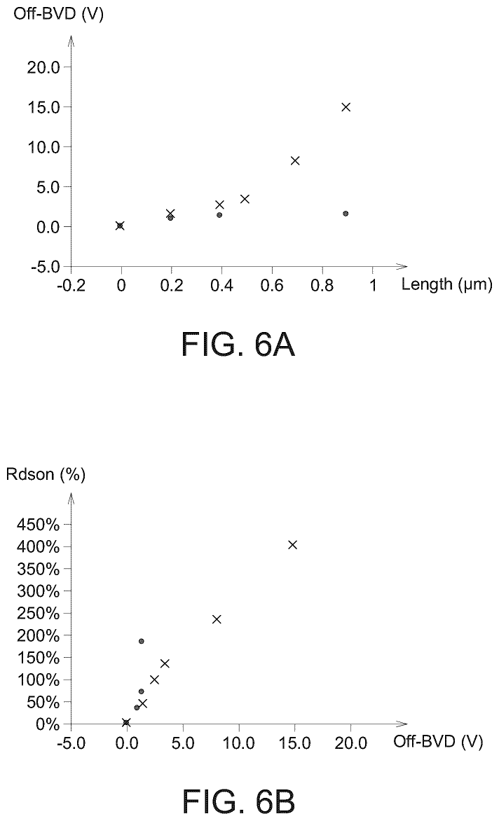

FIGS. 6A and 6B shows testing results of semiconductor structures according to some embodiments of the present disclosure. The horizontal axis in FIG. 6A represents a length difference between a length of the isolation structure between a first well and a second well of a tested transistor structure in the lateral direction (or can be understood as a distance in the lateral direction between the sidewall 121S1 and the sidewall 121S2) and a length of the isolation structure of a standard transistor structure in the lateral direction. The vertical axis in FIG. 6A represents a breakdown voltage difference between a breakdown voltage of a tested transistor structure in an “OFF” state and a breakdown voltage of a standard transistor structure. The horizontal axis in FIG. 6B a breakdown voltage difference between a breakdown voltage of a tested transistor structure in an “OFF” state and a breakdown voltage of a standard transistor structure. The vertical axis in FIG. 6B represents the percentage of the on-resistance of the tested transistor structure in an “OFF” state relative to the on-resistance of the standard transistor structure. In FIGS. 6A and 6B, symbol “x” represents the transistor structure of the present disclosure, and symbol “•” represents the transistor structure of the comparative example. In the transistor structure of the comparative example, the isolation structure in a well and the lower surface of the isolation structure is completely covered by this well. As shown in FIG. 6A, when the lengths of the isolation structures are the same, the transistor structure of the present disclosure has a higher breakdown voltage; the breakdown voltage of the transistor structure of the present disclosure increases significantly as the length of the isolation structure increases. As shown in FIG. 6B, although increasing the breakdown voltage will lead to an increase in on-resistance, the transistor structure of the present disclosure can keep the on-resistance within an appropriate range, and the semiconductor structure has excellent electrical performance. Therefore, by making at least a portion of the lower surface of the isolation structure not covered by the well, the present disclosure can effectively increase the breakdown voltage, maintain a good balance between the breakdown voltage and the on-resistance, and improve the reliability and operation stability of the semiconductor structure. Moreover, the transistor structure of the present disclosure is compatible with existing manufacturing processes of metal oxide semiconductor and does not require additional photomasks. The manufacturing cost of the semiconductor structure of the present disclosure is low and the semiconductor structure of the present disclosure is easy to manufacture.

It is noted that the structures as described above are provided for illustration. The disclosure is not limited to the configurations disclosed above. Other embodiments with different configurations of known elements can be applicable, and the exemplified structures could be adjusted and changed based on the actual needs of the practical applications. It is, of course, noted that the configurations of figures are depicted only for demonstration, not for limitation. Thus, it is known by people skilled in the art that the related elements and layers in a semiconductor structure, the shapes or positional relationship of the elements and the procedure details could be adjusted or changed according to the actual requirements.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor structure, comprising:
a substrate;
a first well in the substrate and having a first side surface;
a second well in the substrate and having a second side surface;
a third well in the substrate, wherein the second well is between the first well and the third well;
an isolation structure in the substrate and between the first well and the second well;
a drain region in the first well;
a source region in the third well; and
a gate structure on the substrate,
wherein the first side surface of the first well faces the second side surface of the second well, and the first side surface of the first well is apart from the second side surface of the second well.

2. The semiconductor structure according to claim 1, wherein the first well has a first conductivity type, the second well has the first conductivity type, and the third well has a second conductivity type different from the first conductivity type.

3. The semiconductor structure according to claim 1, wherein the isolation structure comprises a first portion overlapping the first well in a longitudinal direction and a second portion overlapping the second well in the longitudinal direction.

4. The semiconductor structure according to claim 1, wherein the isolation structure has a first sidewall and a second sidewall opposite to the first sidewall, at least one of a distance between the first sidewall and the first side surface of the first well and a distance between the second sidewall and the second side surface of the second well is greater than zero.

5. The semiconductor structure according to claim 4, wherein the first sidewall of the isolation structure is covered by the first well, and the second sidewall of the isolation structure is covered by the second well.

6. The semiconductor structure according to claim 5, wherein current flows from the source region to the drain region through the third well, the second well, the substrate and the first well.

7. The semiconductor structure according to claim 1, wherein the isolation structure has a first sidewall and a second sidewall opposite to the first sidewall, a distance between the first sidewall and the first side surface of the first well is equal to zero, and a distance between the second sidewall and the second side surface of the second well is equal to zero.

8. The semiconductor structure according to claim 7, wherein the first sidewall of the isolation structure is covered by the first well, and the second sidewall of the isolation structure is covered by the second well.

9. The semiconductor structure according to claim 1, wherein the isolation structure has a first sidewall and a second sidewall opposite to the first sidewall, the first side surface of the first well is aligned with the first sidewall of the isolation structure in a longitudinal direction, and/or the second side surface of the second well is aligned with the second sidewall of the isolation structure in the longitudinal direction.

10. The semiconductor structure according to claim 1, wherein at least a portion of a lower surface of the isolation structure is not covered by the first well and the second well.

11. The semiconductor structure according to claim 1, wherein at least a portion of a lower surface of the isolation structure directly contacts the substrate.

12. The semiconductor structure according to claim 1, wherein the isolation structure has a first sidewall and a second sidewall opposite to the first sidewall, a distance between the first sidewall and the first side surface of the first well is equal to a distance between the second sidewall and the second side surface of the second well.

13. The semiconductor structure according to claim 1, wherein current flows from the source region to the drain region through the third well, the second well, the substrate and the first well.

14. The semiconductor structure according to claim 1, wherein a lower surface of the isolation structure is higher than a lower surface of the first well and a lower surface of the second well.

15. The semiconductor structure according to claim 1, wherein the gate structure overlaps the isolation structure, and the gate structure partially overlaps the isolation structure the third well.

16. The semiconductor structure according to claim 1, wherein the second well adjoins the third well.

17. The semiconductor structure according to claim 1, further comprising a doping region and another isolation structure in the third well, wherein the doping region and the source region are separated by the another isolation structure.

18. The semiconductor structure according to claim 17, wherein the source region has a first conductivity type, the drain region has the first conductivity type, and the doping region has a second conductivity type different from the first conductivity type.

19. The semiconductor structure according to claim 18, wherein the substrate has the second conductivity type.

20. The semiconductor structure according to claim 1, wherein the first side surface of the first well and the second side surface of the second well are covered by the substrate.
